(19) United States
(12) Patent Application Publication
(10) Pub. No.: US 2023/0317599 A1
(43) Pub. Date: Oct. 5, 2023

(54) SEMICONDUCTOR DEVICE

(71) Applicant: DENSO CORPORATION, Kariya-city (JP)

(72) Inventor: MASAYOSHI NISHIHATA, Kariya-city (JP)

(21) Appl. No.: 18/331,749

(22) Filed: Jun. 8, 2023

Related U.S. Application Data
(63) Continuation of application No. PCT/JP2021/043194, filed on Nov. 25, 2021.

(30) Foreign Application Priority Data
Dec. 22, 2020 (JP) 2020-212680

(51) Int. Cl. H01L 23/522; H01L 29/739

(52) U.S. Cl. CPC H01L 23/5228; H01L 29/7395

(57) ABSTRACT

A semiconductor device comprises a semiconductor substrate including a main surface, an electrode, a voltage resistive structure portion, and an intervening portion. A semiconductor device further comprises a solder and a terminal which is made a metal, is provided on the solder and has a non-wetting portion that is not wetted with the solder. A length of the intervening portion along the main surface is longer than a length of the non-wetting portion of the terminal.

### CROSS REFERENCE TO RELATED APPLICATION

The present application is a continuation application of International Patent Application No. PCT/JP2021/043194 filed on Nov. 25, 2021, which designated the U.S. and is based on and claims the benefit of priority from Japanese Patent Application No. 2020-212680 filed on Dec. 22, 2020, and the entire disclosure of the above application is incorporated herein by reference.

### TECHNICAL FIELD

The disclosure described herein relates to a semiconductor device which includes a semiconductor substrate.

### BACKGROUND

A semiconductor device may include a semiconductor substrate formed with an electrode and a protective film on one surface. A solder is provided on the electrode to solder a terminal electrically and mechanically on the electrode. The electrode may have a soldering surface area that is the same as a soldering surface area of the terminal. Further, the terminal may have a soldering surface area that is smaller than a soldering surface area of the electrode. In those connecting configurations an electric field distribution may be varied depending on a relative location of the electrode and the terminal. In the above aspects, or in other aspects not mentioned, there is a need for further improvements in a semiconductor device.

### SUMMARY

According to one aspect of the present disclosure, a semiconductor device comprising: a semiconductor substrate including a main surface, an electrode provided in a first region of the main surface, a voltage resistive structure portion provided in a second region different from the first region of the main surface, and an intervening portion provided in a third region between the first region and the second region of the main surface; a solder provided on the electrode; and a terminal which is made of metal, is provided on the solder and has a non-wetting portion that is not wetted with the solder, wherein the intervening portion is less likely to be wetted with the solder than the electrode is, and wherein a length of the intervening portion, which is along the main surface and is in an arrangement direction where the first region and the second region are arranged along, is longer than a length of the non-wetting portion in the arrangement direction.

This suppresses the occurrence of electric field concentration in the voltage resistive structure portion.

The reference numerals in parentheses in the appended claims indicate only a correspondence relationship with the configuration described in the embodiment to be described later, and do not limit the technical scope in any way.

### BRIEF DESCRIPTION OF THE DRAWINGS

The disclosure is further described with reference to the accompanying drawings in which:

FIG. 1 is a cross-sectional view explaining a semiconductor device;

FIG. 2 is a top view in which a second solder and a second heat sink are removed from the semiconductor device;

FIG. 3 is a cross-sectional view explaining a first embodiment along a line III-III shown in FIG. 2;

FIG. 4 is a cross-sectional view explaining a connection configuration with a solder according to the first embodiment;

FIG. 5 is a cross-sectional view explaining a second embodiment;

FIG. 6 is a cross-sectional view explaining a modification of the second embodiment;

FIG. 7 is a cross-sectional view explaining a modification of the second embodiment;

FIG. 8 is a cross-sectional view explaining a third embodiment;

FIG. 9 is a cross-sectional view explaining a modification of an intervening portion; and

FIG. 10 is a cross-sectional view explaining a modification of the intervening portion.

### DESCRIPTION OF EMBODIMENT

JP2018-74059A describes a semiconductor device including a semiconductor substrate formed with an electrode and a protective film on one surface, a solder provided on the electrode, and a terminal provided on the solder.

The protective film is formed on one surface of the semiconductor substrate so as to surround the electrodes and the solder. A voltage resistive structure portion such as a guard ring is formed at a portion of the semiconductor substrate where the protective film is formed.

If the terminal shifts toward the voltage resistive structure portion, the electric field distribution between the terminal and the voltage resistive structure portion changes. There may be an electric field concentration in the voltage resistive structure portion.

It is an object of the present disclosure to provide a semiconductor device in which an occurrence of an electric field concentration in the voltage resistive structure portion is suppressed.

The following describe embodiments for carrying out the present disclosure with reference to the drawings. In each embodiment, parts corresponding to the elements described in the preceding embodiments are denoted by the same reference numerals, and redundant explanation may be omitted. When only a part of a configuration is described in an embodiment, the other preceding embodiments can be applied to the other parts of the configuration.

In addition, not only the combination between portions explicitly described that the combination is possible in each embodiment, but also partial combinations between the embodiments, between the embodiment and the modification, and between the modifications can be made if there is no problem in the combination in particular even when not explicitly described.

### First Embodiment

Hereinafter, a mechanical configuration of a semiconductor device 100 is described. Three directions perpendicular to each other are defined as an x-direction, a y-direction, and a z-direction. In the drawings, the description of “direction” is omitted. The z-direction corresponds to a perpendicular direction.

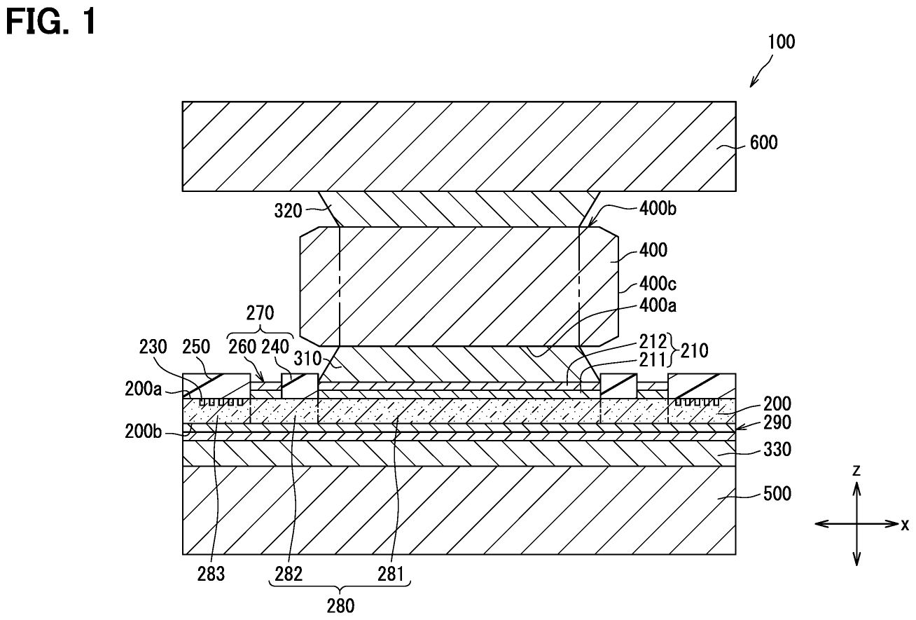

As shown in FIG. 1, the semiconductor device 100 includes a semiconductor substrate 200, a first solder 310, a second solder 320, a third solder 330, a terminal 400, a first heat sink 500, a second heat sink 600, and a plurality of terminals (not shown). The multiple terminals are, for example, a signal terminal, a first main terminal, and a second main terminal etc.

The semiconductor device 100 is known as what is called a 1-in-1 package constituting one arm of a plurality of arms constituting a three-phase inverter circuit. The semiconductor device 100 is incorporated in, for example, an inverter circuit of a vehicle.

The semiconductor element 200 is formed by forming a power transistor such as an insulated gate bipolar transistor (IGBT) on a semiconductor member such as Silicon or Silicon-carbide. The power transistor forms so called a vertical structure to flow a current the z-direction.

The semiconductor substrate 200 has a flat shape whose thickness in the z-direction is thin. The semiconductor substrate 200 has a first principal surface 200a and a second principal surface 200b on the back side of the first principal surface 200a, which are spaced apart in the z-direction. The first main surface 200a corresponds to the main surface.

The semiconductor substrate 200 has an emitter electrode 210, a plurality of pads 220, a plurality of voltage resistive structure portions 230, a first protective film 240, a second protective film 250, a dummy electrode 260 and a collector electrode 290 in addition to the first main surface 200a and the second main surface 200b.

As shown in FIGS. 1 to 4, the emitter electrode 210, the plurality of pads 220, the plurality of voltage resistive structure portions 230, the first protective film 240, the second protective film 250, and the dummy electrodes 260 are provided to the first main surface 200a of the semiconductor substrate 200. The collector electrode 290 is provided on the second main surface 200b of the semiconductor substrate 200. Note that the emitter electrode 210 corresponds to an electrode. The first protective film 240 corresponds to the first structural portion. The dummy electrode 260 corresponds to the second structural portion.

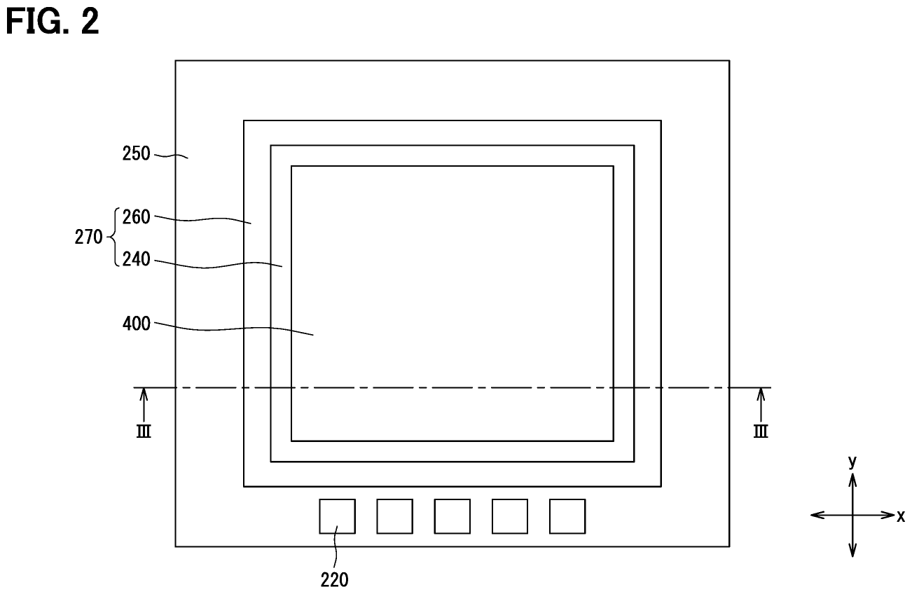

The pad 220 is an electrode for a signal. As shown in FIG. 2, the plurality of pads 220 are provided on a side of an end of the semiconductor substrate 200 in the y-direction. The plurality of pads 220 are exposed from the second protective film 250.

Each of the plurality of pads 220 is used, for example, for a gate electrode, for a Kelvin emitter, for a current sense, for an anode potential of a temperature sensor, and for a cathode potential of the temperature sensor as well. The plurality of pads 220 are electrically connected to a plurality of signal terminals (not shown) via bonding wires (not shown).

The terminal 400 is a block body having a substantially rectangular parallelepiped shape. As shown in FIG. 2, the terminal 400 has a pair of a first terminal surface 400a and a second terminal surface 400b on the back side of the first terminal surface 400a which are arranged to be separated from each other in the z-direction, and four coupling terminal surfaces 400c which couple the first terminal surface 400a and the second terminal surface 400b.

The terminal 400 is electrically and mechanically connected to the emitter electrode 210 via the first solder 310. The second heat sink 600 is electrically and mechanically connected to the terminal 400 through the second solder 320.

The terminal 400 is located in a middle of a thermal and electrical conduction paths between the semiconductor substrate 200 and the second heat sink 600. The terminal 400 is formed by using a metal member having excellent thermal conductivity and electrical conductivity, such as copper.

The first heat sink 500 has a flat plate shape. There is a first main terminal, not shown, continuous to the first heat sink 500. The first main terminal is electrically connected to the collector electrode 290 of the semiconductor substrate 200.

The first heat sink 500 has a heat dissipation function of dissipating heat of a power transistor formed in the semiconductor substrate 200 to an outside of the semiconductor substrate 200, and a function of electrically joining the collector electrode 290 and the first main terminal.

The first heat sink 500 is electrically and mechanically connected to the semiconductor substrate 200 via a third solder 330. Similar to the terminal 400, the first heat sink 500 is formed by using a metal member excellent in thermal conductivity and electrical conductivity, such as copper.

The first main terminal may be formed integrally with the first heat sink 500 as a part of a lead frame or may be formed as a separate member from the first heat sink 500.

The second heat sink 600 also has a flat plate shape. There is a second main terminal, not shown, continuous to the second heat sink 600. The second main terminal is electrically connected to the emitter electrode 210 of the semiconductor substrate 200.

The second heat sink 600 has a heat dissipation function of dissipating heat of a power transistor formed in the semiconductor substrate 200 to an outside of the semiconductor substrate 200, and a function of electrically joining the emitter electrode 210 and the second main terminal.

Similar to the terminal 400 and the first heat sink 500, the second heat sink 600 is formed by using a metal member excellent in thermal conductivity and electrical conductivity, such as copper.

The second main terminal may be formed integrally with the second heat sink 600 as a part of a lead frame or may be formed as a separate member from the second heat sink 600.

### <Semiconductor Substrate>

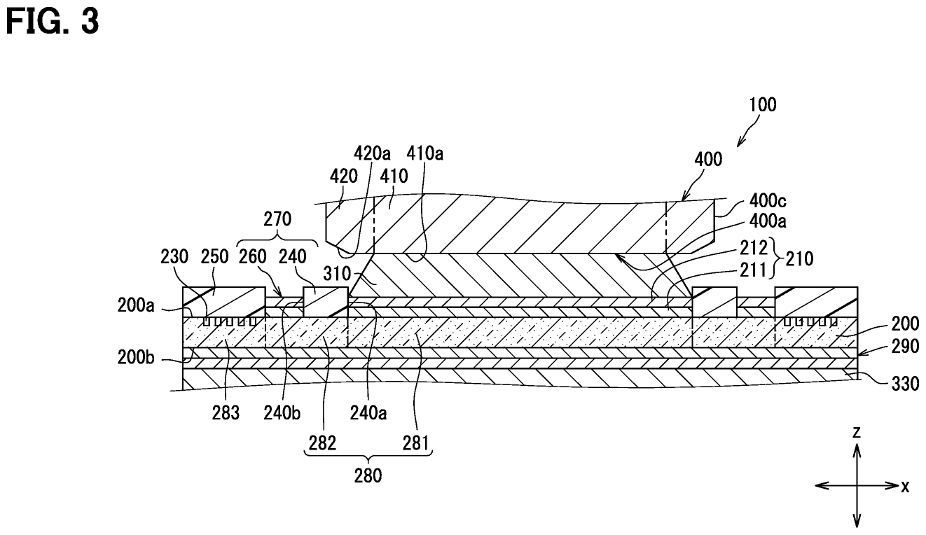

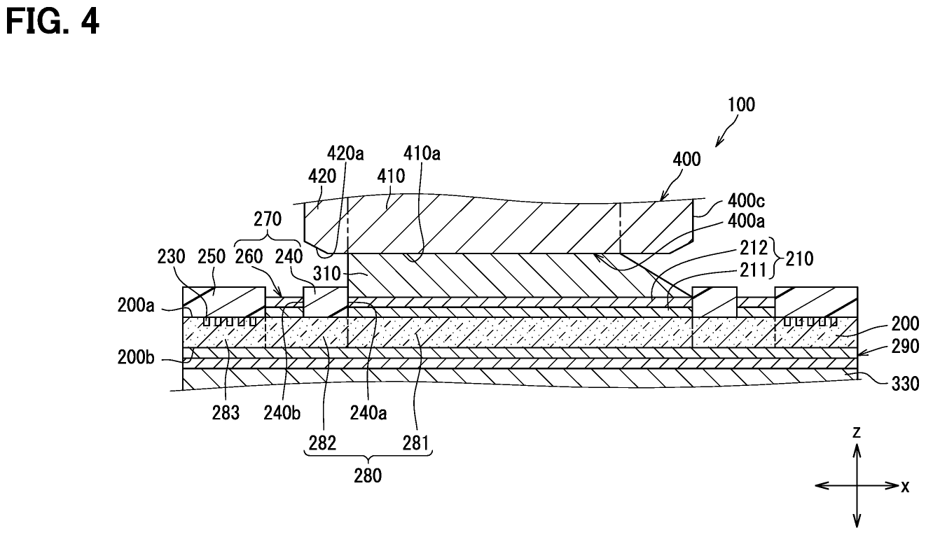

The detailed structure of the semiconductor substrate 200 is described with reference to FIG. 3 and FIG. 4. Although not shown, a power transistor is provided on a surface layer on a side of the first main surface 200a of an active region 280 extending a predetermined distance in a plane direction from a center in a plane direction along the main surface of the semiconductor substrate 200.

In other words, the power transistor is provided at a portion corresponding to the active region 280 on the first main surface 200a. In order to simplify the description, a portion corresponding to the active region 280 on the first main surface 200a is simply referred to as the active region 280 hereinafter.

Also, the active region 280 is surrounded in a circumferential direction around the z-direction by a voltage resistive structure region 283 in which a plurality of voltage resistive structure portions 230 such as guard rings are provided. A plurality of voltage resistive structure portions 230 are provided in the surface layer on a side of the first main surface 200a of the voltage resistive structure region 283.

That is, a plurality of voltage resistive structure portions 230 are provided at portions corresponding to the voltage resistive structure region 283 of the first main surface 200a. In order to simplify the explanation, the portion corresponding to the voltage resistive structure region 283 of the first main surface 200a is simply referred to as the voltage resistive structure region 283 hereinafter.

A plurality of voltage resistive structure portions 230 are arranged in the x-direction in the voltage resistive structure region 283. Note that the voltage resistive structure portion 230 need not be a guard ring as long as it has a function of maintaining breakdown voltage of the power transistor. The voltage resistive structure region 283 corresponds to the second region.

In the drawing, a boundary between the active region 280 and the voltage resistive structure region 283 is indicated by a dashed line.

The active area 280 also comprises a first active area 281 and a second active area 282 surrounding the first active area 281 in a circumferential direction around the z-direction. In the drawing, a boundary between the first active region 281 and the second active region 282 is indicated by a dashed line. Note that the first active region 281 corresponds to the first region. The second active area 282 corresponds to the third region.

The second active region 282 is provided between the first active region 281 and the voltage resistive structure region 283 in an arrangement direction in which the first active region 281 and the voltage resistive structure region 283 are arranged along the first main surface 200a.

Note that the power transistor does not have to be provided in both the first active region 281 and the second active region 282. The power transistor should be provided at least in the first active region 281.

In order to simplify the description, a portion corresponding to the active region 281 on the first main surface 200a is simply referred to as the active region 281 hereinafter. A portion of the first main surface 200a corresponding to the second active region 282 is simply referred to as the second active region 282.

### <Emitter Electrode>

The emitter electrode 210 has a base electrode 211 and a top electrode 212. The base electrode 211 is provided in the first active region 281. The base electrode 211 is electrically connected to the power transistor provided in the first active region 281.

The base electrode 211 is formed by using a material containing aluminum as its main component. A thickness of the base electrode 211 is, for example, 5 μm.

The top electrode 212 is formed at a portion of the base electrode 211 away from the first main surface 200a for the purpose of improving a bonding strength and a solder wettability with the first solder 310. The top electrode 212 is formed by using a material containing nickel as a main component, for example. A thickness of the top electrode 212 is about 5 μm to 10 μm. The top electrode 212 may employ a multi-layer structure. Note that the collector electrode 290 also has a similar structure.

### <First Protective Film>

The first protective film 240 is made of a member that is less likely to be wetted with the first solder 310 than the emitter electrode 210 is. For example, the first protective film 240 is polyimide, resist, or the like. As shown in FIGS. 1 to 4, the first protective film 240 has an annular shape surrounding the emitter electrode 210.

More specifically, the first protective film 240 is provided in the second active region 282 of the first main surface 200a so as to surround the emitter electrode 210 in the circumferential direction around the z-direction. The first protective film 240 is adjacent to the emitter electrode 210 in the arrangement direction.

### <Dummy Electrode>

A dummy electrode 260 has the same configuration as the emitter electrode 210. As shown in FIGS. 1 to 4, the dummy electrode 260 has an annular shape surrounding the first protective film 240.

More specifically, the dummy electrode 260 has an annular shape surrounding the first protective film 240 in the circumferential direction around the z-direction. The dummy electrode 260 is provided in the second active region 282 so as to surround the first protective film 240 in the circumferential direction around the z-direction. The dummy electrode 260 is adjacent to the first protective film 240 in the arrangement direction.

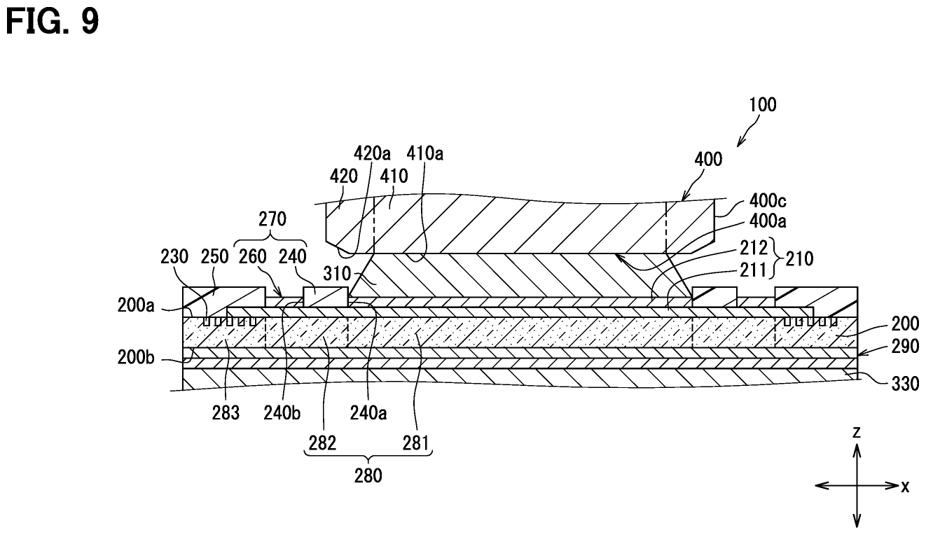

Also, as shown in FIGS. 3 and 4, the dummy electrode 260 is electrically isolated from the emitter electrode 210. Note that the dummy electrode 260 does not have to be electrically isolated from the emitter electrode 210 as shown in FIG. 9. In that case, the dummy electrode 260 and the emitter electrode 210 may be the same potential.

### <Second Protective Film>

The second protective film 250 is made of a member that is less likely to be wetted with the first solder 310 than the emitter electrode 210 is. For example, the second protective film 250 is polyimide, resist, or the like. As shown in FIGS. 1 to 4, the second protective film 250 has an annular shape surrounding the dummy electrode 260.

More specifically, the second protective film 250 is provided in the voltage resistive structure region 283 of the first main surface 200a so as to surround the dummy electrode 260 in the circumferential direction around the z-direction. The second protective film 250 is adjacent to the dummy electrode 260 in the arrangement direction.

As described above, a plurality of voltage resistive structure portions 230 are provided in the voltage resistive structure region 283. A plurality of voltage resistive structure portions 230 are covered with the second protective film 250.

### <First Protective Film, Second Protective Film, and Dummy Electrode>

As described above, the first protective film 240 has an annular shape surrounding the emitter electrode 210. The dummy electrode 260 has an annular shape surrounding the first protective film 240. The second protective film 250 has an annular shape surrounding the dummy electrode 260. The dummy electrode 260 is provided all around in the circumferential direction between the first protective film 240 and the second protective film 250 in the arrangement direction.

The dummy electrode 260 has a composition different from that of the first protective film 240 and the second protective film 250. The dummy electrode 260 serves to indicate the boundary between the first protective film 240 and the second protective film 250.

### <Potential of Semiconductor Substrate>

Assuming that a potential of the emitter electrode 210 is at the GND level and a potential of the collector electrode 290 is approximately 1200V, potentials at respective portions of the semiconductor substrate 200 approaches the potential of the collector electrode 290 as a distance from the emitter electrode 210 increases. A potential of each portion in the region including the second active region 282 and the voltage resistive structure region 283 approaches a potential of the collector electrode 290 as a distance from the emitter electrode 210 increases.

### <Positional Relationship of Semiconductor Substrate and Terminal>

The terminal 400 is electrically and mechanically connected to the emitter electrode 210 via the first solder 310 as described above. As shown in FIGS. 1-4, the terminal 400 overlaps all of the emitter electrodes 210 in the z-direction. In addition, all of the terminals 400 overlap the part where the emitter electrode 210 and the first protective film 240 are combined in the z-direction.

If it is explained about lengths, a length of the terminal 400 in the x-direction is longer than a distance between two portions arranged in the x-direction of the inner surface 240a, which forms an annular shape on a side of the emitter electrode 210, of the first protective film 240. Similarly, a length of the terminal 400 along the y-direction is longer than a distance between two portions arranged in the y-direction of the inner surface 240a, which forms an annular shape on a side of the emitter electrode 210, of the first protective film 240.

Also, a length of the terminal 400 in the x-direction is shorter than a distance between two portions arranged in the x-direction of the outer surface 240b, which forms an annular shape on a side of the dummy electrode 260, of the first protective film 240. Similarly, a length of the terminal 400 in the y-direction is shorter than a distance between two portions arranged in the y-direction of the outer surface 240b, which forms an annular shape on a side of the dummy electrode 260, of the first protective film 240.

<Length Relationship Between Portion Including First Protective Film and Dummy Electrode and Portion of Terminal not Wetted with First Solder>

Hereinafter, in order to simplify the description, a portion where the first protective film 240 and the dummy electrode 260 are combined is referred to as an intervening portion 270. As shown in FIGS. 3 and 4, the first protective film 240 and the dummy electrode 260 are arranged in the arrangement direction. The intervening portion 270 is provided between the emitter electrode 210 and the second protective film 250 in the arrangement direction along all around in the circumferential direction.

Before describing a length relationship between the intervening portion 270 and a portion of the terminal 400 that is not wetted with the first solder 310, a form of connection between the terminal 400 and the emitter electrode 210 via the first solder 310 is described.

As described above, the first protective film 240 is provided on the first main surface 200a so as to surround the emitter electrode 210 in the circumferential direction.

Therefore, the first solder 310 is provided between the terminal 400 and the emitter electrode 210 so as to be away from the intervening portion 270. As shown in FIGS. 3 and 4, the first solder 310 forms a substantially frustum shape between the terminal 400 and the emitter electrode 210.

A portion of the terminal 400, which is wetted with the first solder 310 and connected to the semiconductor substrate 200, is hereinafter referred to as a terminal connecting portion 410. A portion of the terminal 400, which is not wetted with the first solder 310 at a surrounding portion of the terminal connection portion 410 in the circumferential direction and is not connected to the semiconductor substrate 200, is referred to as a terminal outer peripheral portion 420.

A terminal connection surface 410a on a side of the emitter electrode 210 of the terminal connection portion 410 is wetted with the first solder 310 and connected to the semiconductor substrate 200. A terminal outer peripheral surface 420a of the terminal outer peripheral portion 420 on a side of the emitter electrode 210 is not wetted with the first solder 310 and is not connected with the semiconductor substrate 200.

The terminal connection surface 410a and the terminal outer peripheral surface 420a are combined to form a first terminal surface 400a. In the drawing, a boundary between the terminal connecting portion 410 and the terminal outer peripheral portion 420 is indicated by chain double-dashed lines. The terminal outer peripheral portion 420 corresponds to the non-wetting portion.

As shown in FIGS. 3 and 4, a length in the x-direction of one end side of the terminal outer peripheral portion 420 in the x-direction is shorter than a width in the x-direction of the one end side of the intervening portion 270 in the x-direction. A length in the x-direction of the other end side of the terminal outer peripheral portion 420 in the x-direction is shorter than a width in the x-direction of the other end side of the intervening portion 270 in the x-direction.

Although not shown, a length in the y-direction of one end side of the terminal outer peripheral portion 420 in the y-direction is shorter than a width in the y-direction of the one end side of the intervening portion 270 in the y-direction. A length in the y-direction of the other end side of the terminal outer peripheral portion 420 in the y-direction is shorter than a width in the y-direction of the other end side of the intervening portion 270 in the y-direction.

The lengths of the four corners of the terminal outer peripheral portion 420 in the x-direction and the y-direction are shorter than the widths of the four corners of the intervening portion 270 in the x-direction and the y-direction.

As described above, it is designed that the length of the intervening portion 270 in the arrangement direction is always longer than the length of the terminal outer peripheral portion 420 in the arrangement direction. As shown in FIG. 4, it is designed that even if the terminal 400 slides on the first solder 310 and moves toward the voltage resistive structure region 283, the length of the intervening portion 270 in the arrangement direction is always longer than the length of the terminal outer peripheral portion 420 in the arrangement direction.

The length of the terminal outer peripheral portion 420 in the arrangement direction corresponds to a length that is expected to be shorter than the length of the intervening portion 270 in the arrangement direction.

### Second Embodiment

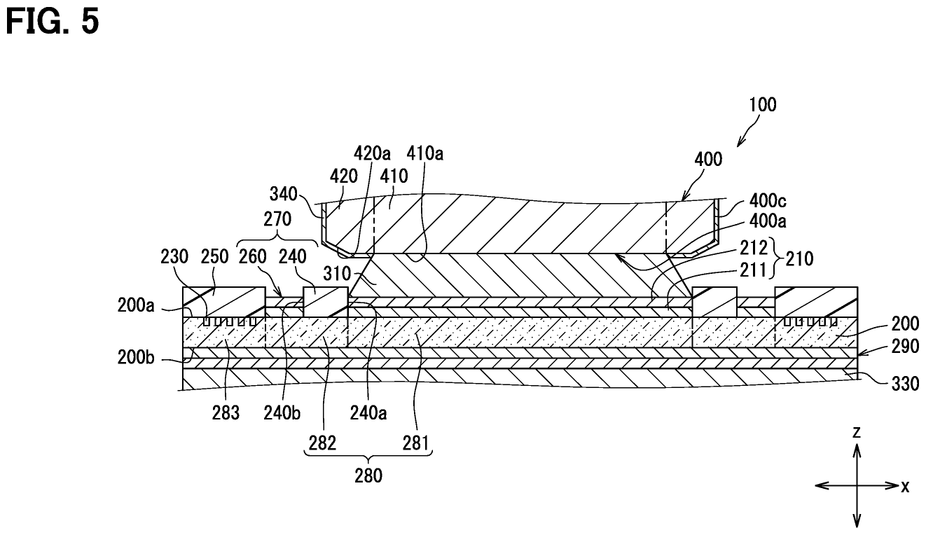

As a second embodiment, the terminal 400 has a roughened film 340 which is less likely to be wetted with the first solder 310 and the second solder 320 than the terminal 400 is. As shown in FIG. 5, a roughened film 340 is provided on the connecting terminal surface 400c and the terminal outer peripheral surface 420a.

The roughened film 340 may be intentionally provided on the terminal outer peripheral surface 420a, or may be at least provided on the terminal outer peripheral surface 420a in an unintentional manner. For example, the roughened film 340 may be provided on the terminal outer peripheral surface 420a during a process of providing the roughened film 340 on the connecting terminal surface 400c. Note that the roughened film 340 is an oxide film. The roughened film 340 corresponds to a solder prevention film.

The roughened film 340 is formed by forming an uneven shape on a metal thin film made of metal. The roughened film 340 of this embodiment is mainly composed of nickel. The metal thin films are formed by, for example, plating or vapor deposition.

As described above, the roughened film 340 is made of a material that is less likely to be wetted with the first solder 310 and the second solder 320 than terminal 400 is. Therefore, the first solder 310 and the second solder 320 are less likely to wet and spread on the connecting terminal surface 400c. Furthermore, the first solder 310 is less likely to wet and spread on the terminal outer peripheral surface 420a.

Also in the second embodiment, the length of the intervening portion 270 in the arrangement direction is designed to be always longer than the length of the terminal outer peripheral portion 420 in the arrangement direction.

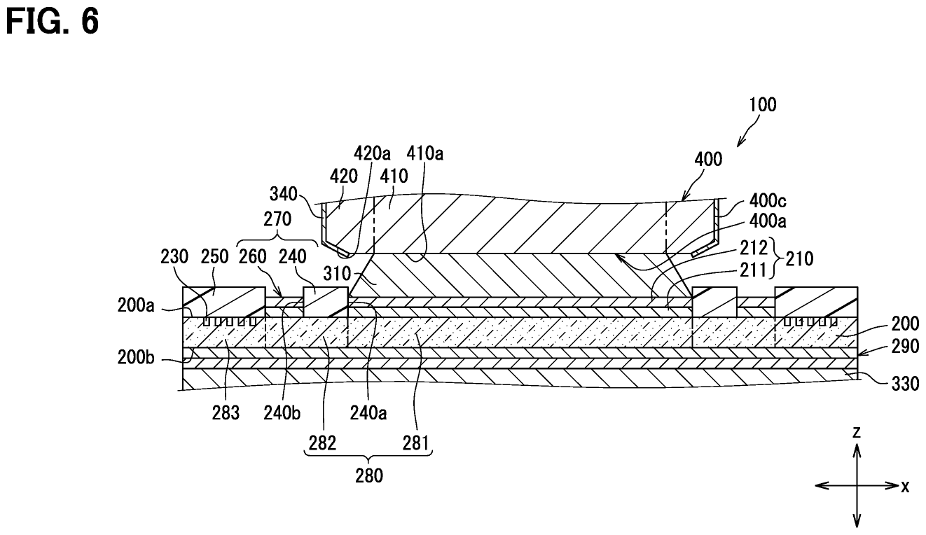

Further, as shown in FIG. 6, the roughened film 340 may not be provided on an entire of the terminal outer peripheral surface 420a. The terminal outer peripheral surface 420a may include a portion where the roughened film 340 is provided and a portion where the roughened film 340 is not provided.

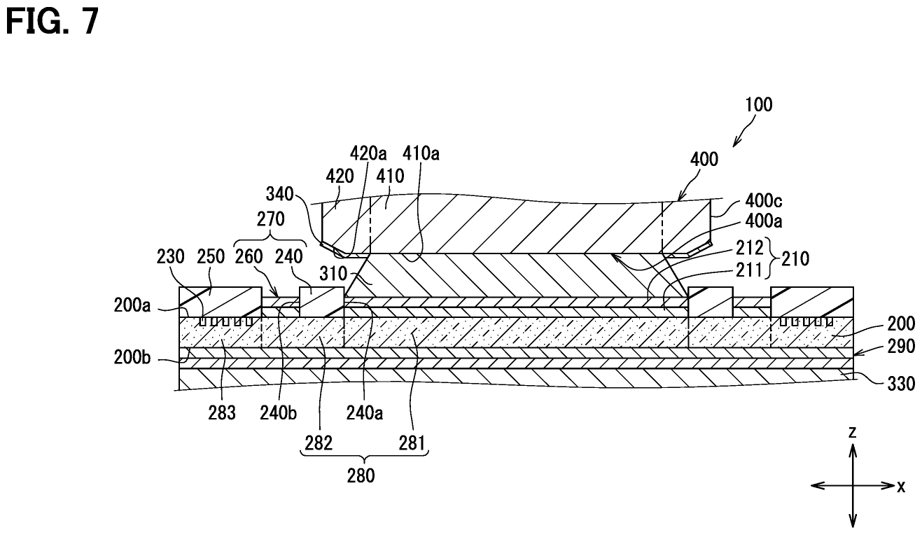

Also, as shown in FIG. 7, the roughened film 340 may not be provided on both the connecting terminal surface 400c and the terminal outer peripheral surface 420a. The roughened film 340 may be provided only on the terminal outer peripheral surface 420a.

### Third Embodiment

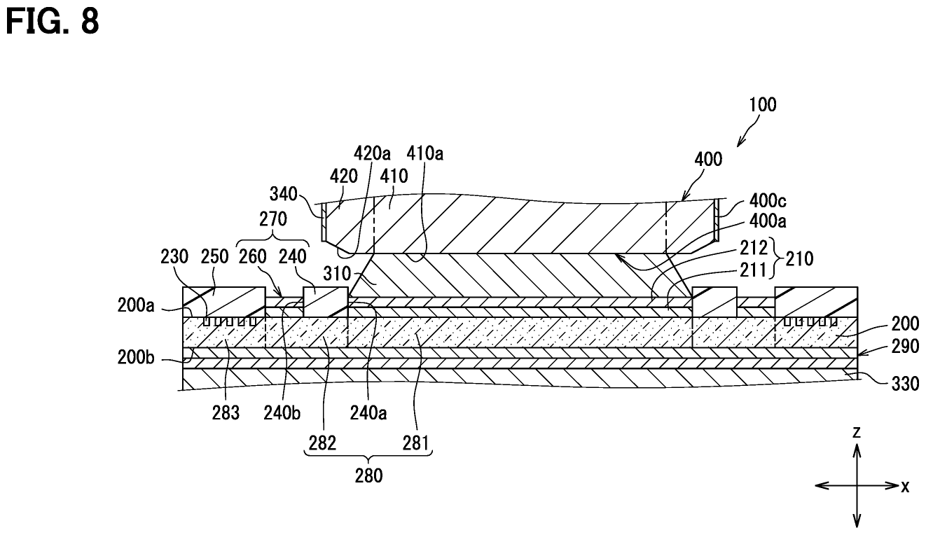

Further, as shown in FIG. 8, the roughened film 340 may be provided only on the connecting terminal surface 400c, instead of the roughened film 340 is not provided on both the connecting terminal surface 400c and the terminal outer peripheral surface 420a.

Also in the third embodiment, the length of the intervening portion 270 in the arrangement direction is designed to be always longer than the length of the terminal outer peripheral portion 420 in the arrangement direction.

### First Modification

In the first embodiment, the second embodiment, and the third embodiment described so far, the configurations in which the dummy electrode 260 is electrically isolated from the emitter electrode 210 are described. However, the dummy electrode 260 and the emitter electrode 210 may be the same potential by integrally connecting the base electrode 211 of the emitter electrode 210 and the base electrode 211 of the dummy electrode 260 as shown in FIG. 9. A part of the base electrode 211 may be covered with the first protective film 240 and the second protective film 250 respectively.

### Second Modification

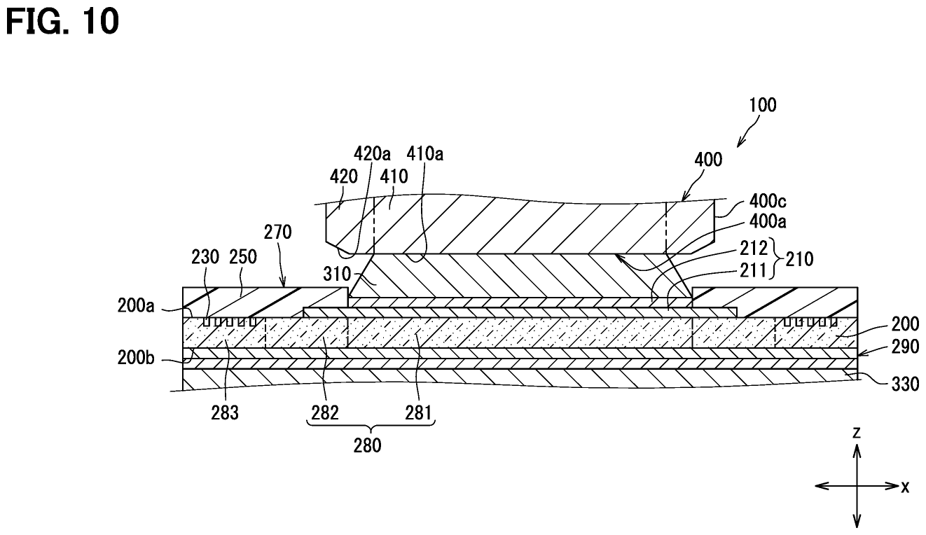

In the first embodiment, the second embodiment, and the third embodiment described so far, the configurations in which the intervening portion 270 includes both the first protective film 240 and the dummy electrode 260 are described. However, as shown in FIG. 10, the intervening portion 270 does not have to include the dummy electrode 260. The intervening portion 270 may include only the first protective film 240. A part of the base electrode 211 may be covered with the first protective film 240. The first protective film 240 and the second protective film 250 may be integrally connected.

### <Operations and Advantages>

As described above, the intervening portion 270 is provided between the emitter electrode 210 and the second protective film 250 in the arrangement direction along all around in the circumferential direction. It is designed that the length of the intervening portion 270 in the arrangement direction is always longer than the length of the terminal outer peripheral portion 420 in the arrangement direction.

Therefore, for example, as shown in FIG. 4, even if the terminal 400 slides on the first solder 310 and moves toward the voltage resistive structure region 283, the terminal 400 is always separated from the voltage resistive structure region 283 in the arrangement direction.

If the terminal 400 approaches a side of the voltage resistive structure region 283, the electric field distribution between the voltage resistive structure region 283 and the terminal 400 changes. If the terminal 400 moves to the vicinity of the voltage resistive structure region 283, the electric field distribution between the voltage resistive structure portion 230 provided in the voltage resistive structure region 283 and the terminal 400 changes. At that time, the electric field concentration tends to occur in the voltage resistive structure portion 230. In particular, if the terminal 400 faces the voltage resistive structure 230 in the z-direction, the electric field concentration tends to occur in the voltage resistive structure 230.

However, in the first to third embodiments and modified examples, the terminal 400 is always separated from the voltage resistive structure region 283 in the x-direction as described above. An end portion on a side of the voltage resistive structure region 283 of the terminal outer peripheral portion 420 faces the second active region 282 in the z-direction. Therefore, the occurrence of the electric field concentration in the voltage resistive structure portion 230 is easily suppressed. A variation in the potential of the voltage resistive structure 230 is easily suppressed. Along with this, fluctuations in a withstand voltage of the power transistors are more likely to be suppressed.

As described above, the roughened film 340 is provided on the terminal outer peripheral surface 420a. As described above, the length of the intervening portion 270 in the arrangement direction is designed to be longer than the length of the terminal outer peripheral portion 420 in the arrangement direction. Therefore, the length of the intervening portion 270 in the arrangement direction is easily defined.

The terminal 400 and the emitter electrode 210 are connected via the first solder 310 as described above. The terminal 400 overlaps all of the emitter electrode 210 in the z-direction. Therefore, heat of the semiconductor substrate 200 is easily dissipated to the terminal 400.

As described above, the dummy electrode 260 are provided between the first protective film 240 and the second protective film 250 in the arrangement direction along all around in the circumferential direction. Therefore, whether or not the terminal 400 faces the second protective film 250 in the z-direction can be easily determined based on a visible appearance. It is possible to improve an efficiency of appearance inspection.

What is claimed is:

1. A semiconductor device, comprising:
a semiconductor substrate including a main surface, an electrode provided in a first region of the main surface, a voltage resistive structure portion provided in a second region different from the first region of the main surface, and an intervening portion provided in a third region between the first region and the second region of the main surface;
a solder provided on the electrode; and
a terminal which is made a metal, is provided on the solder and has a non-wetting portion that is not wetted with the solder, wherein
the intervening portion is less likely to be wetted with the solder than the electrode is, and wherein
a length of the intervening portion, which is along the main surface and is in an arrangement direction where the first region and the second region are arranged along, is longer than a length of the non-wetting portion in the arrangement direction.

2. The semiconductor device according to claim 1, wherein
the terminal further has a solder prevention film that is less likely to be wetted with the solder than the terminal is, and
the solder prevention film is provided on at least a portion of the non-wetting portion on a side of the main surface.

3. The semiconductor device according to claim 1, wherein
an entire of the electrode overlaps the terminal in a perpendicular direction perpendicular to the main surface.

4. The semiconductor device according to claim 1, wherein
the intervening portion includes:
a first structural portion which is less likely to be wetted by the solder than the electrode and forms an annular shape, which is adjacent to the electrode in the arrangement direction and extends in a circumferential direction about a perpendicular direction perpendicular to the main surface; and
a second structural portion which has a composition different from that of the first structural portion, is less likely to be wetted by the solder than the electrode and forms an annular shape, which is adjacent to the first structural portion in the arrangement direction and extends in the circumferential direction.

5. The semiconductor device according to claim 4, wherein
the second structural portion and the electrode are the same potential.
